(19) United States
(12) Patent Application Publication
(10) Pub. No.: US 2024/0181401 A1
(43) Pub. Date: Jun. 6, 2024

(54) MECHANICALLY COMPLIANT NANOFIBROUS BARRIER

(71) Applicant: Infineon Technologies AG, Neubiberg (DE)

(72) Inventors: Sebastian Anzinger, Miesbach (DE); Hutomo Suryo Wasisto, München (DE); Sebastian Schwagerl, Cham (DE)

(21) Appl. No.: 18/520,028

(22) Filed: Nov. 27, 2023

(30) Foreign Application Priority Data
Dec. 1, 2022 (EP) 22210899
Dec. 1, 2022 (EP) 22210912
Sep. 21, 2023 (EP) 23198792

(51) Int. Cl. B01D 67/00

(52) U.S. Cl. CPC B01D 67/0079; B01D 67/00042; B01D 67/0034; B01D 67/00412; B01D 67/0093; B01D 2325/30

(57) ABSTRACT

A method for producing a microstructured air-permeable environmental barrier membrane includes providing a substrate, and structuring a through hole into the substrate, the through hole extending fully through the substrate between two opposite surfaces of the substrate, leaving the through hole uncovered, and depositing one or more nanofibers onto at least one of the two opposite substrate surfaces by applying at least one of an electrospinning or blowspinning method, such that the spun nanofibers combine to a network of nanofibers that forms a free-standing and mechanically compliant nanofibrous membrane covering the previously uncovered through hole.

This application claims priority from European Patent Application No. 22210912, filed Dec. 1, 2022, European Patent Application No. 22210899, filed Dec. 1, 2022, and European Patent Application No. 23198792, filed Sep. 21, 2023, which applications are hereby incorporated herein by reference

### TECHNICAL FIELD

Embodiments of the present disclosure relate to a micromechanical environmental barrier membrane for providing a protection for microelectronic mechanical system (MEMS)-based sound and/or pressure devices against ingress of environmental solid, gaseous and/or moist particles. Further embodiments relate to a manufacturing method thereof.

### BACKGROUND OF THE INVENTION

Next generation silicon MEMS-based microphones, and potentially also other sensors, are expected to have environmental barriers (EBs) in their package construction to be able to withstand harsh environmental conditions, including impacting solid objects (e.g., dust particles and hairs) and high water ingression. Typical environmental barrier structures are known to be integrated on application system level, e.g., somewhere in the sound channel.

### SUMMARY

According to a first aspect, a method includes providing a substrate, and structuring a through hole into the substrate, the through hole extending fully through the substrate between two opposite surfaces of the substrate. The method further includes leaving the through hole uncovered and depositing nanofibers onto at least one of the two opposite substrate surfaces by applying at least one of an electrospinning or blowspinning method, such that the spun nanofibers combine to a network of nanofibers that forms a free-standing and mechanically compliant nanofibrous membrane covering the previously uncovered through hole.

According to a second aspect, a second method for producing an air-permeable environmental barrier membrane includes providing a substrate having a first substrate surface and an opposite second substrate surface, and depositing a sacrificial layer onto at least one of the two opposite substrate surfaces. The method further includes structuring a through hole into the substrate, the through hole extending fully through the substrate between two opposite substrate surfaces, where the sacrificial layer remains and covers the through hole. The method further includes depositing nanofibers onto the sacrificial layer by applying at least one of electrospinning or blowspinning methods, such that the spun nanofibers combine to a network of nanofibers that forms a nanofibrous membrane. The method further includes removing the sacrificial layer for releasing the nanofibrous membrane, where the released nanofibrous membrane forms a free-standing and mechanically compliant nanofibrous membrane that covers the through hole.

Furthermore, an environmental barrier chip with an air-permeable environmental barrier membrane is disclosed, the environmental barrier chip including a substrate including a through hole extending fully through the substrate between two opposite substrate surfaces. A free-standing and mechanically compliant nanofibrous membrane is arranged on at least one of the two opposite surfaces of the substrate, such that the nanofibrous membrane covers the through hole. According to the herein described disclosure, the nanofibrous membrane is formed by a network of spun nanofibers being arranged on at least one of the two opposite surfaces of the substrate.

### BRIEF DESCRIPTION OF THE DRAWINGS

In the following, embodiments of the present disclosure are described in more detail with reference to the figures, in which

FIG. 1A shows a side elevational view of an environmental barrier chip including a free-standing mechanically compliant environmental barrier membrane according to an embodiment,

FIG. 1B shows a top view onto an environmental barrier chip including a free-standing mechanically compliant environmental barrier membrane according to an embodiment,

FIG. 1C shows a perspective view of an environmental barrier chip including a free-standing mechanically compliant environmental barrier membrane according to an embodiment,

FIG. 2A shows an exploded perspective view of an environmental barrier chip including a free-standing mechanically compliant environmental barrier membrane according to an embodiment,

FIG. 2B shows a side elevational view of an environmental barrier chip including a free-standing mechanically compliant environmental barrier membrane according to an embodiment,

FIG. 3A shows an exploded perspective view of an environmental barrier chip including a free-standing mechanically compliant environmental barrier membrane being manufactured by an alternative method according to an embodiment,

FIG. 3B shows a side elevational view of an environmental barrier chip including a free-standing mechanically compliant environmental barrier membrane being manufactured by an alternative method according to an embodiment,

FIGS. 4A-4D show the density distribution of deposited nanofibers during a proceeding application time,

FIGS. 5A-5B show side elevational views of an environmental barrier chip including a free-standing mechanically compliant environmental barrier membrane according to an embodiment,

FIGS. 6A-6D show a process flow of a first method for manufacturing an environmental barrier chip with a free-standing mechanically compliant environmental barrier membrane according to an embodiment,

FIGS. 7A-7E show a process flow of a second method for manufacturing an environmental barrier chip with a free-standing mechanically compliant environmental barrier membrane according to an embodiment,

FIG. 8A shows an exploded perspective view of an environmental barrier chip including a mechanically compliant environmental barrier membrane being supported by an environmental barrier structure that is configured as a mechanically compliant perforated membrane,

FIG. 8B shows a top view onto the environmental barrier chip with the environmental barrier structure applied thereon,

FIG. 8C shows a top view onto the environmental barrier chip of FIG. 8B with an additional nanofibrous environmental barrier membrane,

FIGS. 9A-9B shows side elevational views of the environmental barrier chip according to FIGS. 8A-8C with and without a force being applied to the environmental barrier structure, and

FIGS. 10A-10D show a process flow of a method for manufacturing the environmental barrier chip according to FIGS. 8A-8C with a mechanically compliant environmental barrier membrane.

### DETAILED DESCRIPTION OF ILLUSTRATIVE EMBODIMENTS

Equal or equivalent elements or elements with equal or equivalent functionality are denoted in the following description by equal or equivalent reference numerals.

Method steps which are depicted by a block diagram and which are described with reference to the block diagram may also be executed in an order different from the depicted and/or described order. Furthermore, method steps concerning a particular feature of a device may be replaceable with the feature of the device, and vice versa. Certain method steps may be omitted or rearranged in various embodiments.

Environmental barrier structures should affect the function of a MEMS device as little as possible, i.e., the use of an environmental barrier structure should not negatively affect the acoustic performance of the MEMS device (e.g., signal-to-noise (SNR) ratio). Thus, when designing environmental barrier structures, it is desirable to provide a high mechanical compliance/flexibility of the environmental barrier structure while at the same time providing a high air flow through the environmental barrier structure. In other words, an environmental barrier structure should include a low acoustic/airflow resistance and a high mechanical compliance at the same time. However, this is a trade-off because a low acoustical resistance typically means an increased airflow through the material (larger pores or larger open area) and therefore a reduced protection from dust and water ingress. On the other hand, a higher acoustic resistance typically means a reduced airflow through the material (due to less perforation or open area) and therefore an improved protection from dust and water ingress on the cost of SNR.

Some environmental barrier structures may include a highly compliant/flexible environmental barrier membrane being made from expanded polytetrafluoroethylene (ePTFE). The ePTFE membrane may be attached to a carrier frame to support the construction and to enable bonding and mounting of the environmental barrier structure onto a printed circuit board (PCB) inside or outside the package. This environmental barrier structure may be integrated in the package during the backend packaging process or on system level during an assembly process. Some known problems of these environmental barrier structures are mainly their high costs related with the individual single-unit production of each environmental barrier structure.

Thus, it would be desirable to provide an environmental barrier structure for MEMS-based acoustic and/or pressure devices, the environmental barrier structure including a low acoustic/airflow resistance and a high mechanical compliance at the same time, while keeping manufacturing costs at a moderate level.

These goals can be achieved with a method for producing a microstructured air-permeable environmental barrier membrane in accordance with the herein described disclosure, as well as with an environmental barrier chip including a microstructured air-permeable environmental barrier membrane, as disclosed herein.

The herein described nanofibrous air-permeable environmental barrier membrane, as well as the environmental barrier chip including the nanofibrous air-permeable environmental barrier membrane, can be used to protect MEMS devices in general from harmful environmental influences. The nanofibrous air-permeable environmental barrier membrane may be particularly useful to protect MEMS pressure transducers, such as MEMS pressure sensors, MEMS microphones, and MEMS speakers. In the following description of the Figures, MEMS microphones and MEMS speakers are used as non-limiting examples for MEMS devices in general.

Upon designing environmental barrier structures for MEMS devices, such as MEMS microphones or MEMS speakers, it can be desirable to provide a grid/mesh with a high grid/mesh density in order to improve the environmental protection level (to be able to withstand e.g., water ingression at a certain pressure/depth). Furthermore, it would be desirable to provide rigid meshes for the sake of stability. However, at the same time, maintaining good acoustic performance is desirable, which may be accomplished with free-standing flexible membranes where acoustic energy can be transferred via membrane oscillations (mechanical compliance).

Accordingly, there is a trade-off between a dense and rigid environmental barrier structure for providing a high protection level with high robustness, and a mechanically compliant/flexible membrane for transferring acoustic energy as lossless as possible.

For example, a given membrane may have a compliant/flexible behavior but a low airflow. A given mesh, in turn, may have a high airflow but a rigid/stiff structure. However, real-life meshes and membranes may lead to some unavoidable degree of signal-to-noise ratio (SNR)-loss.

The herein described disclosure combines the positive characteristics of both membranes and meshes by providing a microstructured air-permeable environmental barrier membrane that is made from spun nanofibers, which combine to a network of nanofibers that forms a free-standing and mechanically compliant nanofibrous membrane, as described in further detail herein.

For ease of understanding of the mechanically compliant nanofibrous membrane, a brief introduction to mechanical compliance shall be given first. In mechanical engineering, a compliant structure is a flexible mechanism that achieves force and motion transmission through elastic body deformation. The compliant structure gains some or all of its motion from the relative flexibility of its members rather than from rigid-body joints alone. The compliant structure may thus include monolithic (single-piece) or jointless structures.

Compliant structures are often created as an alternative to similar mechanisms that use multiple parts. There are two main advantages for using compliant structures. First, a compliant structure can be fabricated into a single structure, which is a simplification in the number of parts used, thereby leading to low manufacturing costs. Second, compliant structures can have a better efficiency since they do not suffer from some issues that affect multi-bodied mechanisms, such as backlash or surface wear. Due to the usage of flexible elements, compliant structures can easily store energy to be released at a later time or transformed into other forms of energy.

Accordingly, a mechanically compliant membrane may be included under the above mentioned compliant structures. A mechanically compliant membrane is a flexible membrane that is able to oscillate in response to applied acoustic energy, and which returns back to an initial state when the acoustic energy is not applied anymore.

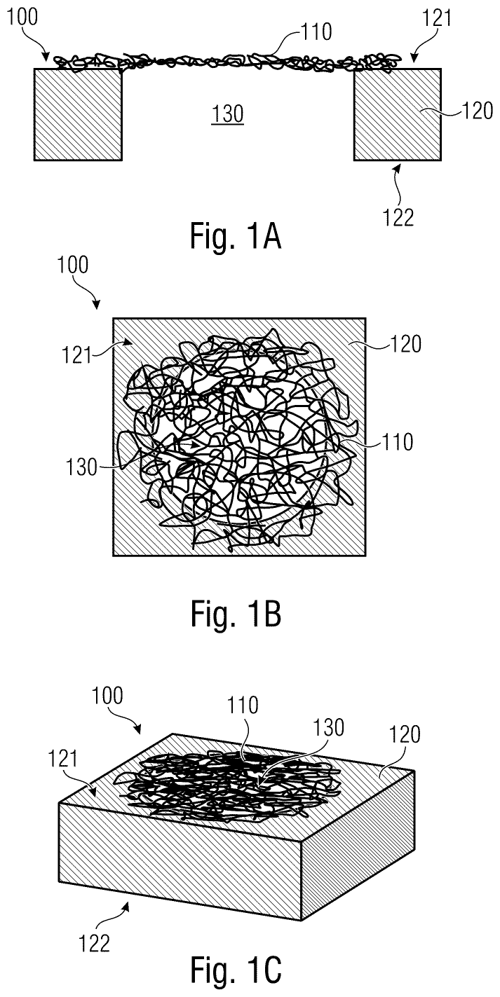

FIGS. 1A, 1B and 1C show a side elevational view, a top view and a perspective view of a single environmental barrier chip 100 according to an embodiment including an air-permeable environmental barrier membrane 110. The environmental barrier chip 100 includes a substrate 120 having a through hole 130 extending fully through the substrate 120 between two opposite surfaces 121, 122 of the substrate 120. The substrate 120 may include a semiconductor material, glass, a polymer or any other suitable material.

The through hole 130 may include any kind of geometrical shape, e.g., circular, rectangular, triangular, oval, pentagonal, hexagonal, octagonal. Furthermore, the through hole 130 may extend straight through the substrate 120 or in a bend/curved shape. The through hole 130 may extend vertically through the substrate 120, i.e., orthogonally to the two opposite substrate surfaces 121, 122, or it may extend with any skew angle (different from an orthogonal 90°-angle) between the first and second substrate surfaces 121, 122.

A free-standing and mechanically compliant nanofibrous membrane 110 is arranged on at least one of the two opposite surfaces 121, 122 of the substrate 120, such that the nanofibrous membrane 110 covers the through hole 130. In this non-limiting example, the membrane 110 may be arranged on a first substrate surface 121.

In the embodiments shown in FIGS. 1A, 1B and 1C the nanofibrous membrane 110 is arranged on one of the two opposite surfaces 121, 122 of the substrate 120. However, it may also be possible that the depicted nanofibrous membrane 110 may be arranged on the second substrate surface 122, or that an additional second nanofibrous membrane may be provided, where a first nanofibrous membrane 110 may be arranged on the first substrate surface 121 and a second nanofibrous membrane 110 may be arranged on the second substrate surface 122 opposite the first substrate surface 121.

According to the herein described disclosure, the nanofibrous membrane 110 is formed by a network of spun nanofibers being deposited/spun onto at least one of the two opposite surfaces 121, 122 of the substrate 120. After being arranged on the substrate 120, the nanofibrous membrane 110 forms an air-permeable environmental barrier membrane. In other words, the free-standing nanofibrous membrane 110 acts as an air-permeable and mechanically compliant environmental barrier membrane.

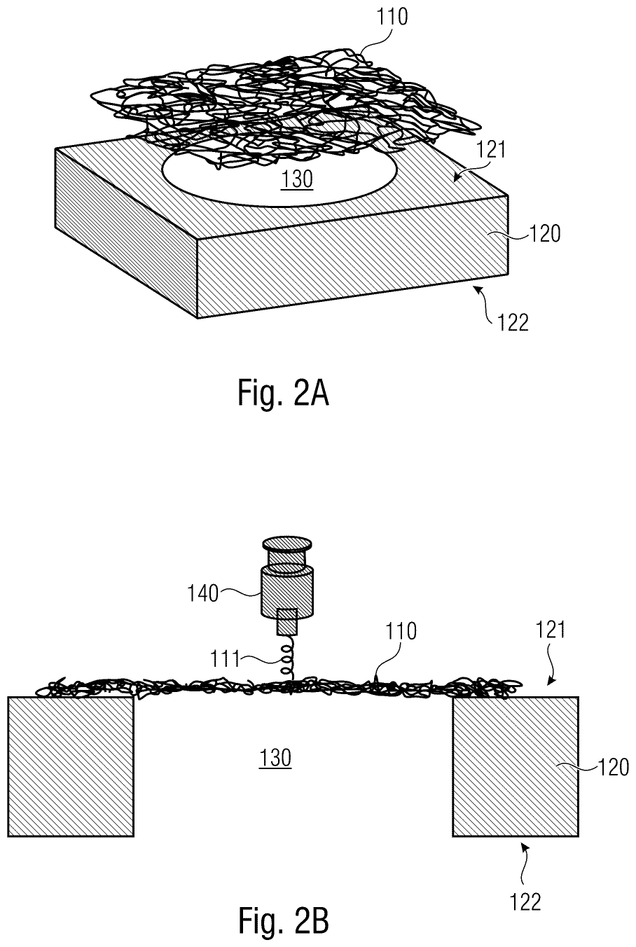

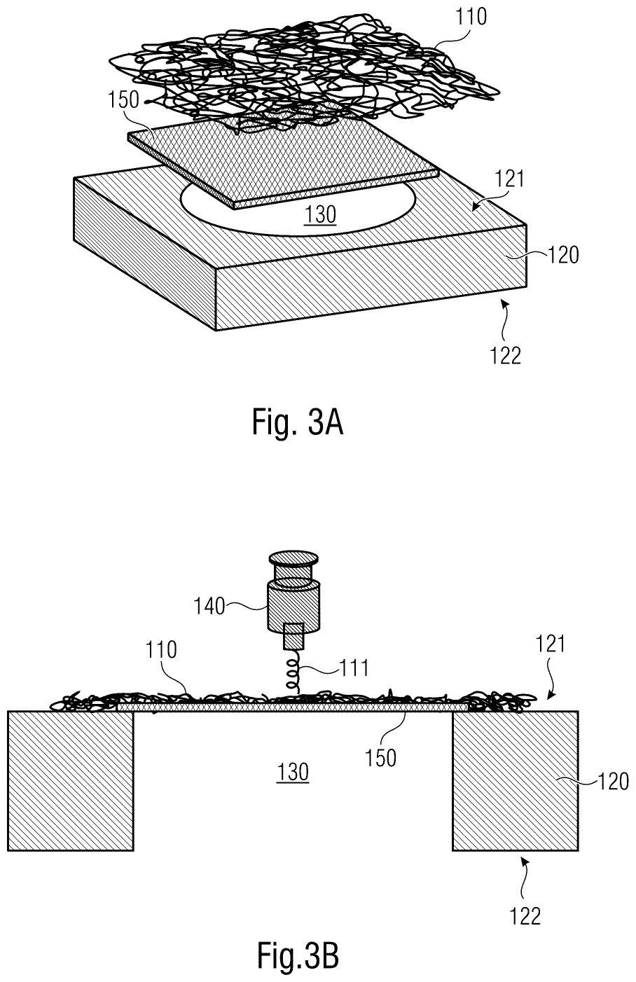

FIGS. 2A and 2B show a first embodiment of a method for manufacturing/producing the microstructured free-standing air-permeable nanofibrous environmental barrier membrane 110. FIGS. 3A and 3B show a second method for manufacturing/producing the microstructured free-standing air-permeable nanofibrous environmental barrier membrane 110. Accordingly, two methods for manufacturing the same device 110 are suggested. Thus, two solutions for the same technical problem are described herein.

According to the first solution, as depicted in FIGS. 2A and 2B, the method includes a step of providing a substrate 120 and structuring a through hole 130 into the substrate 120, the through hole 130 extending fully through the substrate 120 between the two opposite substrate surfaces 121, 122. The through hole 130 may be created by etching, e.g., by deep reactive ion etching (DRIE). An etch stop layer (not shown) may be deposited onto the one of the two substrate surfaces 121, 122.

According to this first solution, the through hole 130 is left open or uncovered. Then, one or more single nanofibers 111 are deposited onto the at least one of the two opposite substrate surfaces 121, 122 by applying an electrospinning or blowspinning method. This is schematically symbolized by tool 140 in FIG. 2B.

In order to obtain an enhanced adhesion of the spun nanofibers 111 at the respective substrate surface 121, 122, an adhesion promotion layer (not shown) may be deposited onto the respective substrate surface 121, 122. The nanofibers 111 may then be deposited/spun onto the adhesion promotion layer.

Upon depositing/spinning the nanofibers 110 onto the respective substrate surface 121, 122 the spun nanofibers 111 may also extend over the through hole 130. The through hole 130 may include a size (e.g., a diameter) that is small enough such that the spun nanofibers 111 do not fall into the through hole 130.

The spun nanofibers 111 may then be combined to a network of nanofibers that forms a free-standing and mechanically compliant nanofibrous membrane 110 that covers the through hole 130 which has been intentionally left uncovered before. In this constellation, the nanofibrous membrane 110 acts as a nanofibrous and mechanically compliant air-permeable environmental barrier membrane. As a result, an environmental barrier chip 100 being equipped with a free-standing and mechanically compliant nanofibrous membrane 110, as described above with reference to FIGS. 1A, 1B and 1C can be obtained.

FIGS. 3A and 3B show a second solution of a method for producing an environmental barrier chip 100 with a nanofibrous air-permeable and mechanically compliant environmental barrier membrane 110. According to this second solution, the through hole 130 is not left uncovered. Instead, prior to structuring the through hole 130 into the substrate 120, a temporary sacrificial layer 150 is deposited onto at least one of the two opposite substrate surfaces 121, 122. Then, the through hole 130 is structured into the substrate 120, such that the through hole 130 fully extends through the substrate 120 between the two opposite substrate surfaces 121, 122 with leaving the temporary sacrificial layer 150 on the respective substrate surface 121. In result, the sacrificial layer 150 covers the through hole 130, i.e., the substrate 120 includes a through hole 130 that is covered by the temporary sacrificial layer 150.

The through hole 130 may be created by etching, e.g., by deep reactive ion etching (DRIE). The through hole 130 may be structured into the substrate 120 starting from the one substrate surface 122 that is opposite to the other substrate surface 121 on which the temporary sacrificial layer 150 is arranged. The through hole 130 may be structured, e.g. etched, until reaching the temporary sacrificial layer 150. In this case, the temporary sacrificial layer 150 may act as a structuring stop layer, e.g., as an etch stop layer. In some embodiments, an additional etch stop layer (not shown) may be deposited between the temporary sacrificial layer 150 and the respective substrate surface 121.

In a next step, one or more single nanofibers 111 may be deposited onto the temporary sacrificial layer 150 by applying an electrospinning or blowspinning method. This is schematically symbolized by tool 140 in FIG. 3B. The spun nanofibers 111 combine to a network of nanofibers that forms a nanofibrous membrane 110. At this stage, the nanofibrous membrane 110 is supported by the temporary sacrificial layer 150.

In order to obtain an enhanced adhesion of the spun nanofibers 111 at the temporary sacrificial layer 150, an adhesion promotion layer (not shown) may be deposited onto the temporary sacrificial layer 150. The nanofibers 111 may then be deposited/spun onto the adhesion promotion layer.

In a next step, the temporary sacrificial layer 150 is removed in order to release the nanofibrous membrane 110, after which the released nanofibrous membrane 110 forms a free-standing and mechanically compliant nanofibrous membrane 110 covering the through hole 130. In this constellation, the nanofibrous membrane 110 acts as a nanofibrous and mechanically compliant air-permeable environmental barrier membrane.

After removal of the sacrificial layer 150, an environmental barrier chip 100 being equipped with a free-standing and mechanically compliant nanofibrous membrane 110, as described above with reference to FIGS. 1A, 1B and 1C can be obtained. As will be explained below, the sacrificial layer 150 may be removed with different methods.

According to a first case, the step of removing the sacrificial layer 150 may be performed by applying a chemical wet etching process. In this case, the sacrificial layer 150 may be a silicon oxide layer. For example, a silicon oxide may be deposited onto the at least one of the two substrate surfaces 121, 122. This silicon oxide layer 150 may then be removed by chemical wet etching, e.g., by applying hydrogen fluoride (HF) or hydrofluoric acid, respectively.

In the first case, the nanofibers 111 forming the nanofibrous membrane 110 may include, or may be made of, a material being resistant against an etchant (e.g., hydrofluoric acid) being used in the chemical wet etching process. Thus, when applying the wet chemical etching process, the etchant-sensitive sacrificial layer 150 is selectively removed such that the etchant-resistant nanofibrous membrane 110 remains.

According to a second case, the step of removing the sacrificial layer 150 may be performed by applying a high-temperature ashing process, such as plasma ashing, for example. In the second case, the sacrificial layer 150 may include, or may be made of, a carbon-based material for being removed by the high-temperature ashing process. For example, the sacrificial layer 150 may include, or may be made of, pyrolytic carbon or graphene.

The nanofibers 111, in turn, may include, or may be made of, at least one of a high-temperature stable material for withstanding the high-temperature ashing process. For example, the nanofibers 111 may include, or may be made of, at least one of high-temperature stable polymer materials (e.g., polytetrafluoroethylene (PTFE) and polyimide (PI)) or ceramic/metal-oxide-based materials (e.g., aluminum oxide (Al₂O₃), silicon dioxide (SiO₂), tin oxide (SnO₂), and copper oxide (CuO)) or composite materials.

In case of ceramics, the nanofibers 111 may be further processed after electrospinning or blowspinning. For example, the nanofibers 111 may be subjected to a so-called calcination. The nanofibers 111 may be created in hybrid or composite fashion, i.e., one of the polymer types can be combined with others (either another polymer or oxide, or carbon, or other nanomaterials).

Accordingly, one step of the method may include depositing nanofibers 111 including different materials and/or different diameters among each other, i.e., a nanofibrous membrane 110 including nanofibers 111 with different diameters and material types (hybrid) can be produced. For example, different sizes of spinning-material applicators (e.g., needles) can be used when performing electrospinning or blowspinning. In some embodiments, two identical applicators (e.g., needles) may be used, but different material recipes or parameters are used during the spinning process. Regarding a material of the nanofibers 111, more than one material type (hybrid) can be used. Accordingly, nanofibers 111 with more than one diameter size distribution and/or with more than one material source may be produced by subsequent or simultaneous spinning processes, in which the synergistic effects of different nanofibers 111 can then improve the robustness of the nanofibrous membrane 110.

As a further step, the herein described disclosure may include a step of post-processing of the spun nanofibers 111 by applying a solvent vaporization and/or a heat treatment for creating cross-linked nanofibers 111. By doing so, the single spun nanofibers 111 can join and create cross-linked structures among themselves. This may significantly improve a mechanical robustness of the nanofibrous membrane 110. Accordingly, instead of applying one or more separated nanofibers 111, the spun nanofibers 111 can be created in cross-linked structures.

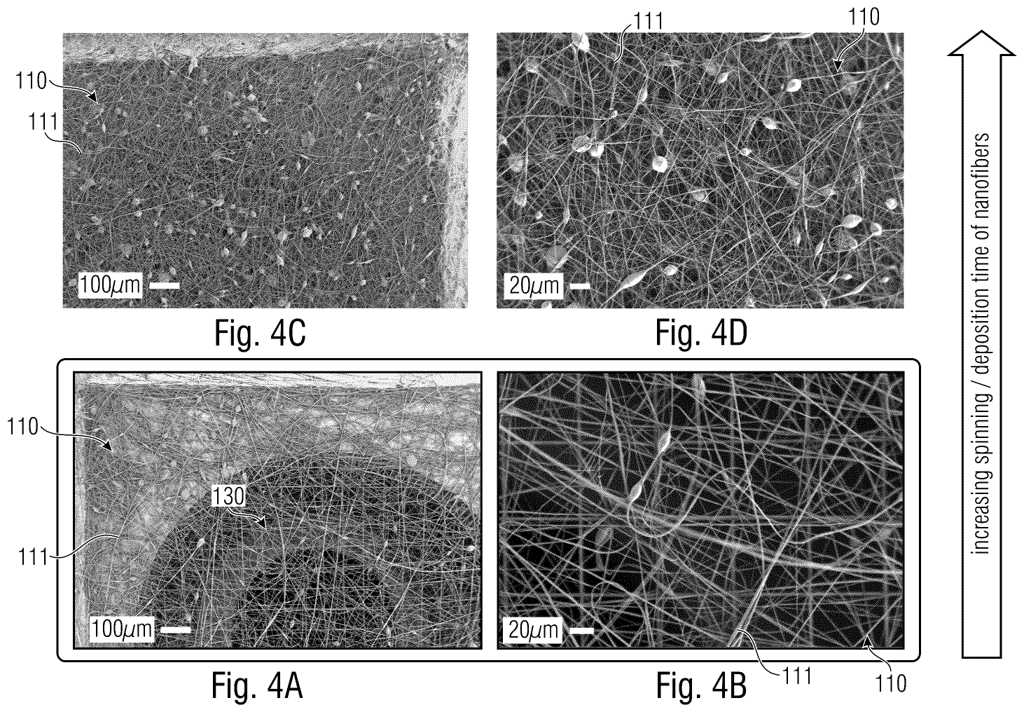

FIGS. 4A to 4D show SEM images of a portion of a nanofibrous membrane 110 being made from spun nanofibers 111. In this non-limiting example, the nanofibers 111 are spun onto a substrate, such as substrate 120 shown in FIG. 2A, with directly covering the through hole 130.

FIG. 4A shows the spun/deposited nanofibers 111 at a resolution of 100 μm. FIG. 4B shows the same SEM image as FIG. 4A but with a higher resolution of 20 μm. As can be seen, the nanofibrous membrane 110 may include a low fiber density.

FIG. 4C shows the same substrate, but in a state in which the spinning/deposition time has been increased compared to FIGS. 4A and 4B. As can be seen, the fiber density can be increased by increasing the spinning/deposition time. FIG. 4D shows the same SEM image as FIG. 4C but with a higher resolution of 20 μm.

In various embodiments, environmental barrier membranes 110 being made from spun nanofibers 111 show a characteristic structure that allows to structurally distinguish them from other environmental barrier membranes which are not made from spun nanofibers 111, such as ePTFE membranes. For example, the nanofibrous membranes 110 may include structural features that do not appear in ePTFE membranes and vice versa.

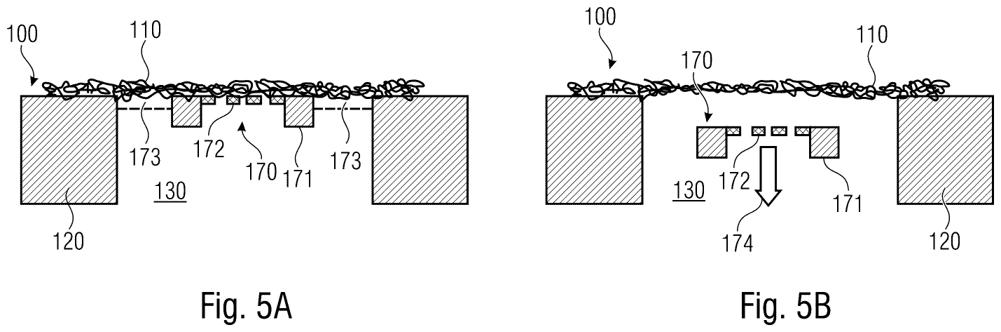

FIGS. 5A and 5B show a third alternative method for producing an environmental barrier chip 100 with a nanofibrous air-permeable and mechanically compliant environmental barrier membrane 110. According to this third alternative, an additional microstructured carrier structure 170 may be provided inside the through hole 130. The carrier structure 170 may be configured as a chip including a substrate 171. The substrate 171 may include, or may be made of, a semiconductor material, glass or polymers. Optionally, the substrate 171 may include a membrane 172. The carrier structure 170 may be suspended inside the through hole 130 by one or more breakable beams 173.

In FIGS. 5A and 5B, the step of depositing the nanofibers 111 may include depositing the nanofibers 111 onto the carrier structure 170, for example onto the substrate 171 and/or the membrane 172. Thus, the carrier structure 170 may act as a support for supporting the spun nanofibers 111 during deposition/spinning.

After the nanofibers 111 have been applied, a step of breaking the breakable beams 173 and removing (as indicated by arrow 174) the carrier structure 170 from the through hole 130 for releasing the nanofibrous membrane 110 made from the deposited nanofibers 111 may be performed.

In the previous description, the disclosure has been exemplarily discussed on chip-level, i.e., with reference to single environmental barrier chips 100. However, one of several advantages of the present disclosure is the possibility of wafer-level processes for parallelizing the manufacturing process in order to enhance the yield and save production costs.

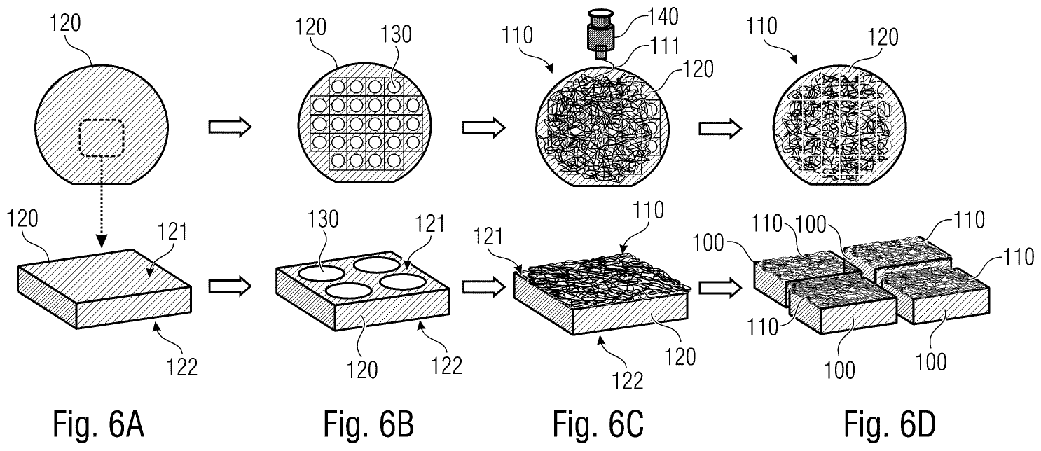

FIGS. 6A to 6D show a process flow for producing a plurality of environmental barrier chips 100 on wafer-level, i.e., the above discussed substrate 120 may be provided as a wafer. The embodiment in FIGS. 6A to 6D may correspond to the previously discussed embodiment as shown in FIGS. 2A and 2B, in which the nanofibers 111 are directly spun onto the substrate 120 without a temporary sacrificial layer 150.

In each of FIGS. 6A to 6D, a respective top drawing shows a top view of the wafer 120, while a bottom drawing shows a perspective view of the wafer 120. FIG. 6A shows the unprocessed bare wafer 120. The wafer 120 may be, for example, a silicon wafer. As can be seen in FIG. 6B, a plurality of the above discussed through holes 130 may be structured into the wafer 120, where each through hole 130 may extend vertically through the wafer 120 between two opposite sides 121, 122 of the wafer 120. The through holes 130 may be created by etching, e.g., by DRIE/Bosch etching.

FIG. 6C shows a further step, in which the nanofibers 111 are deposited onto the at least one of the two opposite wafer surfaces 121, 122 for covering the plurality of through holes 130 provided in the wafer 120. The nanofibers 111 may be deposited e.g., by blowspinning or electrospinning as symbolized by tool 140. An optional adhesion promotion layer (not shown) may be deposited onto the respective wafer surface 121, 122 prior to applying the nanofibers 111. The spun nanofibers 111 combine to a network of nanofibers that forms a free-standing and mechanically compliant nanofibrous membrane 110 covering the plurality of the previously uncovered through holes 130.

FIG. 6D shows a further step in which the individual environmental barrier chips 100 may be singulated from the wafer 120, e.g., by dicing, sawing, etc. In result, a plurality of environmental barrier chips 100 may be created, where each environmental barrier chip 100 includes its own free-standing and mechanically compliant nanofibrous membrane 110.

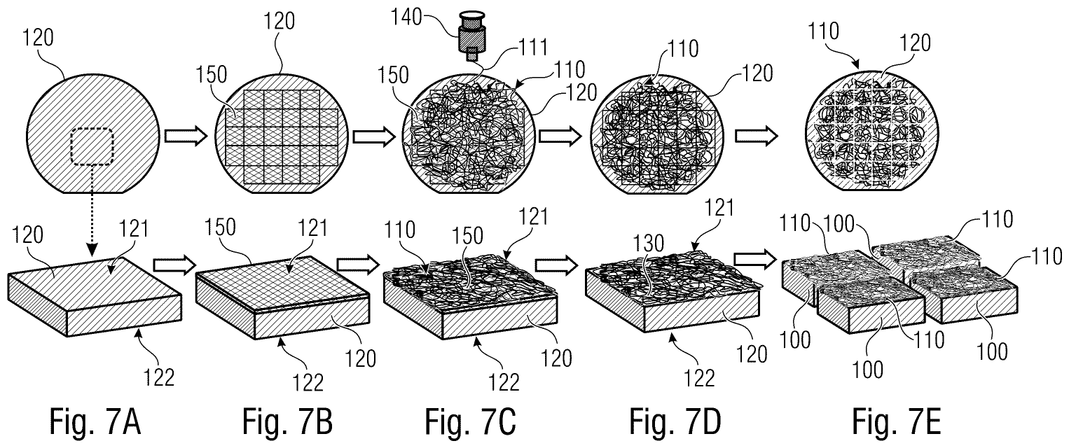

FIGS. 7A to 7E show an alternative process flow for producing a plurality of environmental barrier chips 100 on wafer-level, i.e., the above discussed substrate 120 may again be provided as a wafer. The embodiment of FIGS. 7A to 7E may correspond to the previously discussed embodiment as shown in FIGS. 3A and 3B, in which the nanofibers 111 are spun onto a temporary sacrificial layer 150 being deposited onto the substrate 120.

In each of FIGS. 7A to 7E, a respective top drawing shows a top view of the wafer 120, while a bottom drawing shows a perspective view of the wafer 120. FIG. 7A shows the unprocessed bare wafer 120. The wafer 120 may be, for example, a silicon wafer. As can be seen in FIG. 7B, a temporary sacrificial layer 150 may be deposited onto at least one of the two opposite wafer surfaces 121, 122. In a further method step, the above discussed plurality of through holes 130 may be structured into the wafer 120. They may be structured into the wafer 120 beginning from the opposite second wafer surface 122, i.e., from the opposite side of the deposited temporary sacrificial layer 150. Thus, the through holes 130 are not visible in FIG. 7B.

FIG. 7C shows a further method step in which the nanofibers 111 are deposited onto the temporary sacrificial layer 150, e.g., by blowspinning or electrospinning as symbolized by tool 140. An optional adhesion promotion layer (not shown) may be deposited onto the temporary sacrificial layer 150 prior to applying the nanofibers 111. The spun nanofibers 111 combine to a network of nanofibers that forms a mechanically compliant nanofibrous membrane 110 being supported by the temporary sacrificial layer 150.

FIG. 7D shows a further step in which the temporary sacrificial layer 150 is removed. As discussed above, the temporary sacrificial layer 150 may be removed, for example by etching, ashing or mechanical removal with the help of a support structure 170. By removing the sacrificial layer 150, the through holes 130 become uncovered and thus visible. The nanofibers 111, however, are not removed, i.e., they remain on the at least one wafer surface 121, 122 on which the temporary sacrificial layer 150 was placed before. Since the nanofibrous membrane 110 is now arranged directly on the wafer 120, the nanofibrous membrane 110 now covers the plurality of through holes 130.

FIG. 7E shows a further step in which the individual environmental barrier chips 100 may be singulated from the wafer 120, e.g., by dicing, sawing, etc. In result, a plurality of environmental barrier chips 100 may be created, where each environmental barrier chip 100 includes its own free-standing and mechanically compliant nanofibrous membrane 110.

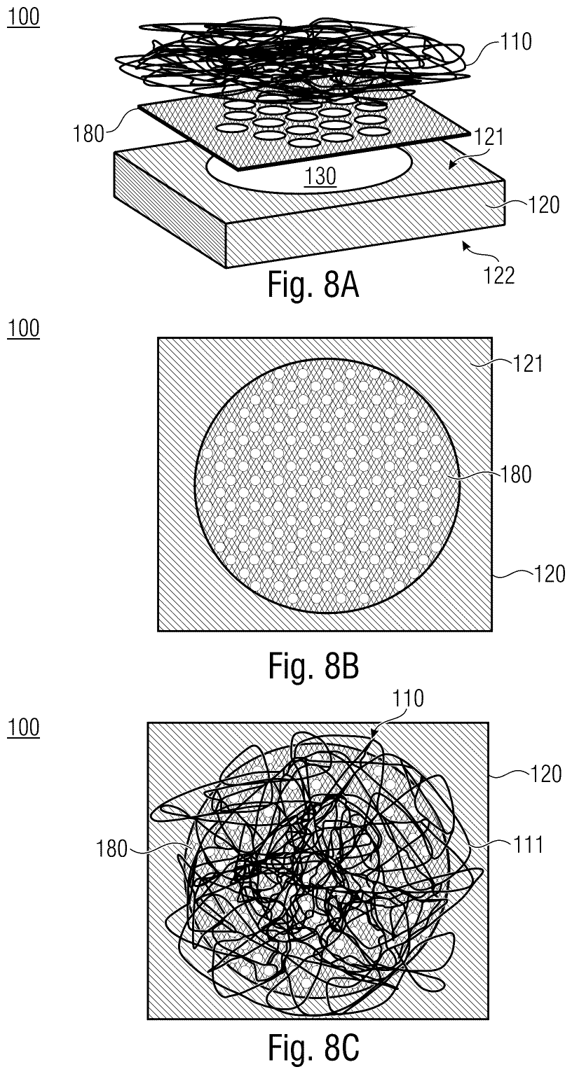

FIGS. 8A to 8C show a further example of producing a plurality of environmental barrier chips 100 on chip-level. This environmental barrier chip 100 may substantially correspond to the above discussed environmental barrier chips 100. Thus, the previous Figures correspond for the environmental barrier chip 100 of FIGS. 8A to 8C.

A difference compared to the previously discussed embodiments is the provision of a environmental barrier structure 180 being permanently arranged between the substrate 120 and the nanofibrous membrane 110, as depicted in the exploded view in FIG. 8A. This environmental barrier structure 180 may correspond to the environmental barrier structure as described in EP 22 210 912.6 and EP 22 210 899.5 which are incorporated by reference herein.

As shown in FIG. 8B, the permanent environmental barrier structure 180 may be arranged on at least one of the two substrate surfaces 121, 122. The environmental barrier structure 180 may be configured as a mechanically compliant/flexible membrane including perforations for allowing a fluid exchange. As shown in FIG. 8C, one or more nanofibers 111 may be deposited/spun onto the environmental barrier structure 180, where the spun nanofibers 111 combine to a network of nanofibers that forms a nanofibrous membrane 110.

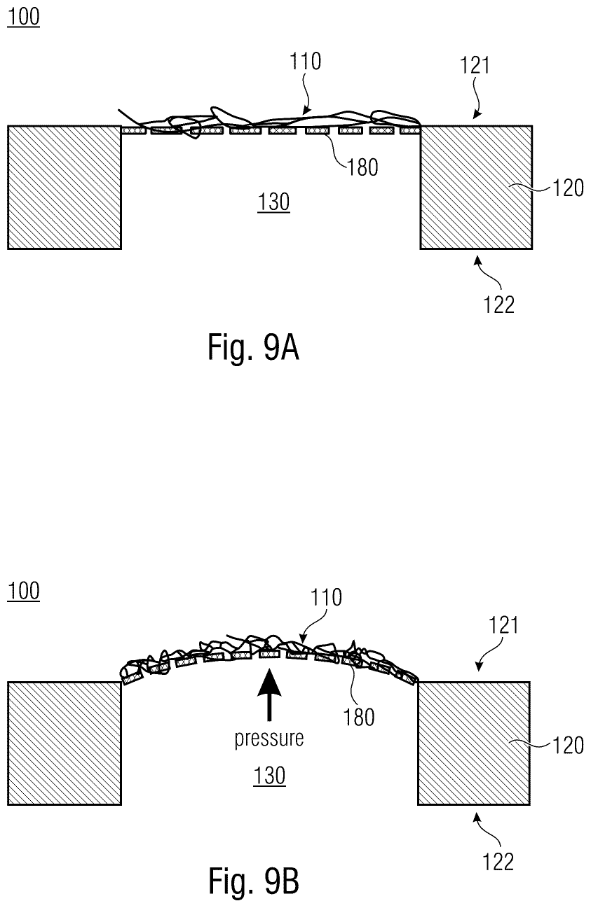

FIGS. 9A and 9B show side elevational views of the environmental barrier chip 100 including the environmental barrier structure 180 with the nanofibrous membrane 110 formed thereon. FIG. 9A shows a situation in which no external force is applied to the environmental barrier structure 180. The environmental barrier structure 180 is in its initial state in which it is not deflected. FIG. 9B shows a scenario in which an external force, e.g., pressure, is applied to the environmental barrier structure 180. Since the environmental barrier structure 180 may be configured as a mechanically compliant/flexible structure, the environmental barrier structure 180 may be deflected in response to the applied force. The nanofibrous membrane 100 may also be deflected together with the environmental barrier structure 180.

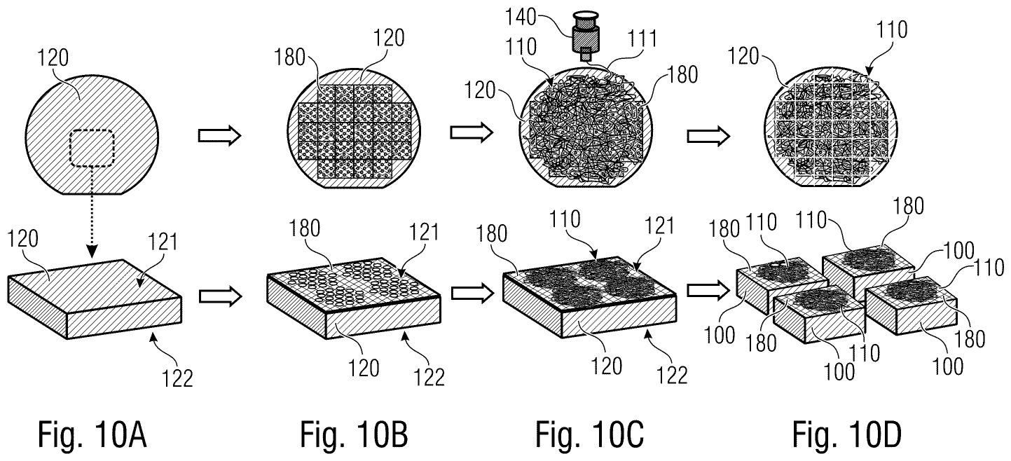

FIGS. 10A to 10D show a process flow for producing a plurality of environmental barrier chips 100 on wafer-level, i.e., the above discussed substrate 120 may again be provided as a wafer. This embodiment may correspond to the previously discussed embodiment as shown in FIGS. 8A to 8C, in which the nanofibers 111 are spun onto a permanent environmental barrier structure 180 being arranged on the substrate 120.

In each of FIGS. 10A to 10D, a respective top drawing shows a top view of the wafer 120, while a bottom drawing shows a perspective view of the wafer 120. FIG. 10A shows the unprocessed bare wafer 120. The wafer 120 may be, for example, a silicon wafer. As can be seen in FIG. 10B, a permanent environmental barrier structure 180 may be arranged on at least one of the two opposite wafer surfaces 121, 122. The permanent environmental barrier structure 180 may be configured as a perforated mechanically compliant membrane. In a further step, the above discussed plurality of through holes 130 may be structured into the wafer 120. They may be structured into the wafer 120 from the opposite second wafer surface 122, i.e., from the opposite side of the permanent environmental barrier structure 180. Thus, the through holes 130 are merely indicated in FIG. 10B underneath the perforations.

FIG. 10C shows a further step in which the nanofibers 111 are deposited onto the permanent environmental barrier structure 180, e.g., by blowspinning or electrospinning as symbolized by tool 140. The spun nanofibers 111 combine to a network of nanofibers that forms a mechanically compliant nanofibrous membrane 110 being supported by the permanent environmental barrier structure 180.

FIG. 10D shows a further step in which the individual environmental barrier chips 100 may be singulated from the wafer 120, e.g., by dicing, sawing, etc. In result, a plurality of environmental barrier chips 100 may be created, where each environmental barrier chip 100 includes its own mechanically compliant nanofibrous membrane 110 being supported by the mechanically compliant permanent environmental barrier structure 180.

Summarizing, the herein described disclosures provides different alternative methods for manufacturing an environmental barrier chip 110 including a nanofibrous and mechanically compliant air-permeable environmental barrier membrane 110. Some embodiments provide devices and fabrication methods of (semiconductor) wafer-level processed environmental barrier modules 100, which include either free-standing or softly (compliant) supported nanofiber membranes 110.

The present disclosure provides different embodiments and manufacturing processes to produce compliant nanofibrous environmental barrier membranes 111 using wafer-level processing combined with spun nanofiber material. Manufacturing costs may be significantly reduced since fabrication techniques from the semiconductor industry, such as wafer-level processing, can be applied.

The structure of interest may include a substrate 120 (single-chip or wafer), with an e.g., deep-reactive-ion-etched (DRIE) through hole 130. At least one side of the through hole 130 may be covered by a network of nanofibers 111 that forms a compliant and air-permeable environmental barrier membrane 110.

In one embodiment (FIGS. 7A-7E), the nanofiber membrane 110 may be deposited on a sacrificial carrier layer 150 that is subsequently removed. According to the embodiment of FIGS. 7A to 7E, the nanofibers 111 may be deposited (e.g., by applying an electrospinning or blowspinning method) on a sacrificial carrier layer 150 covering the though hole 130 of the environmental barrier chip 100. By removing the sacrificial layer 150 (via e.g., etching, ashing, or mechanical removal), a free-standing nanofiber membrane 110 can be released.

An exemplary production process, as depicted in FIGS. 7A-7E, starts with a bare silicon wafer 100. Next, silicon oxide (e.g., tetraethoxysilane (TEOS) or other types of oxide) may be deposited on the wafer 120 which may act as an etch-stop for the DRIE (Bosch) etching and as a sacrificial carrier layer 150 for the nanofibers 111. Subsequently, through holes 130 may be etched through the wafer substrate 120 via Bosch etching. Nanofibers 111 (e.g., polytetrafluoroethylene (PTFE)) may then be deposited on the silicon oxide layer 150 via an electrospinning or blowspinning method. The silicon oxide layer 150 may then be removed via e.g., vapor or liquid HF-etching, releasing a free-standing nanofibrous environmental barrier membrane 110. Considering a production on wafer-level, individual chips 100 may finally be singulated via dicing methods. For instance, individual environmental barrier chips 100 may be singulated via dicing methods to form chips 100 with each containing a nanofibrous and mechanically compliant free-standing environmental barrier membrane 110.

In case the temporary sacrificial layer 150 is removed by etching, a silicon oxide may be used as a carrier layer 150 and an hydrogen fluoride (HF)-resistant material may be used for the nanofibers 111. HF-resistant nanofiber material may include, e.g., noryl, polyethylene, polypropylene (homopolymer), PTFE.

In case the temporary sacrificial layer 150 is removed by ashing (at temperatures of 250° C. and above), a carbon-based carrier layer 150 may be used which can be removed during the ashing process. Nanofiber material may include, e.g., metal oxide or ceramic based nanofibers (e.g., Al₂O₃, SiO₂, SnO₂, CuO) and high temperature stable polymer nanofibers (e.g., PTFE and polyimide (PI) can be selected as the fiber materials).

A further alternative embodiment suggests mechanical removal of a carrier via e.g., breaking device or the so-called chip-in-chip methods. As exemplarily shown in FIGS. 5A and 5B, an inner chip 170 may be suspended inside the through hole 130 by thin beams 173, where an outer chip surface may be covered by a nanofiber network. Breaking out the beam suspended inner chip 170 (by breaking the beams 173) may release a free-standing nanofibrous membrane 110. In case of mechanical removal, the above-mentioned chip-in-chip concept (breaking out inner device 170) may be used, where a low adhesion of the nanofibers 111 may be desirable.

According to a further embodiment, the nanofibers 111 may be directly deposited/spun onto a substrate 120, e.g., onto a pre-structured Si wafer. In this case, the aforementioned temporary sacrificial layer 150 is omitted. Since no additional sacrificial carrier layer 150 is needed, the nanofibers 111 can be directly deposited/spun on a pre-structured Si wafer 120. An exemplary process flow is shown in FIGS. 6A-6D. A bare wafer 120 may be pre-structured to contain vertical through holes 130. Subsequently, the nanofiber network may be deposited over the full wafer 120. Here, the diameter of the through holes 130 may influence the feasibility of the membrane 110 to be stable anchoring on the substrate frame 120. Through holes with too large diameters may lead the nanofibers 111 to fall or drop into it. Thus, the through holes 130 as described herein may include sizes (e.g., diameters) such that the spun nanofibers 111 are not expected to fall into the through hole 130 but still form a nanofibrous membrane 110 on top of the full wafer 120. In a final step, individual environmental barrier chips 100 may be singulated via dicing methods to form chips 100 with each containing a nanofibrous and mechanically compliant free-standing environmental barrier membrane 110.

Each of the herein described environmental barrier chips 100 may be produced on wafer-level with a subsequent chip singulation or on chip-level with single chip processing of the nanofibers 111 on already singulated chips 100.

Due to the fabrication flow and to increase the adhesion of nanofibers 111 with the underlying substrate 120, additional layers may be incorporated, e.g., a silicon oxide layer may remain on the wafer (preferred for Bosch etching and does not need to be removed), or an adhesion promoting layer may be applied to improve stability of the nanofibers 111 on the substrate 120 (e.g., rough surface, adhesion promoting materials).

According to a yet further embodiment, nanofibers 111 may be applied, which are supported by a permanent environmental barrier structure 180, such as a very thin compliant carrier membrane. In this case, the nanofibrous membrane 110 is not free-standing but supported by the environmental barrier structure 180. As exemplarily shown in FIGS. 10A-10D, the nanofibers 111 may be deposited on a very compliant (e.g., very thin) carrier layer 180, which permanently remains as a support structure in the final environmental barrier chips 100.

As shown in FIGS. 10A-10D, an exemplary fabrication process may start on a Si wafer 120, where a layer of the later carrier material 180 will be deposited and structured. Free-standing membranes of the carrier layer 180 may be formed via a backside DRIE process, where a through hole 130 may be created in the wafer substrate 120. Subsequently, the nanofibers 111 may be deposited/spun on the pre-structured wafer 120 followed by a singulation of the wafer 120 into individual environmental barrier chips 100.

Also in this case, theoretically both a wafer-level production with a subsequent chip singulation and single chip processing of the nanofibers 111 on already singulated chips 100 can be done.

The permanent carrier layer 180 may provide some advantageous properties (i.e., high compliance, high perforation/porosity, high temperature stability, and good chemical resistance) to realize an environmental barrier membrane module 100 with low SNR loss that can be later integrated with a microphone package. The materials selected for this carrier layer 180 may be stable during the reflow soldering process (e.g., a peak temperature of 260° C.). Moreover, on the one hand the mechanical compliance of the resulting carrier layer membrane 180 should ideally be larger than the mechanical compliance of the subsequently deposited nanofibers 111 in order to not reduce the mechanical compliance of the environmental barrier membrane stack (including carrier layer 180 and nanofibrous membrane 110) compared to a pure nanofibrous membrane as in the other embodiments. A highly compliant carrier layer 180 may be realized by either depositing a very low intrinsic tensile stress material (ideally stress-free) or depositing a very thin, ideally 2D, material. In previous studies, 100 nm layer of mono-Si showed to be highly compliant. Moreover, carbon-based materials such as graphene, graphenic carbon, and pyrolytic carbon can be used. Depending on the geometries of the created membranes (e.g., membrane thickness and diameter), their mechanical robustness and compliance can be adjusted.

Thin materials may include mono-silicon which shows an extremely high mechanical compliance. Thin materials may further include poly-silicon, which shows a very high mechanical compliance at thicknesses of 150 nm and less. Thin materials may further include carbon-based materials (e.g., graphene, graphenic carbon, pyrolytic carbon). Pyrolytic carbon can demonstrate extremely high mechanical compliances of around 2-20 μm/Pa with high robustness level.

On the other hand, the carrier layer 180 should not significantly alter the air permeability of the environmental barrier membrane stack (carrier layer membrane 180 and nanofibrous membrane 110) compared to a bare nanofibrous membrane as in the other embodiments. Therefore, carrier layer 180 may be perforated or intrinsically nano-/mesoporous.

It is contemplated that environmental barrier chips 100 being manufactured according to one of the herein described embodiments may allow to create MEMS microphones with an integrated environmental protection. MEMS microphones with an integrated environmental protection would simplify the system implementation for manufacturers since they would not have to deal with finding good environmental barrier components and their proper placement in the sound-channel or system.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus.

While this disclosure has been described with reference to illustrative embodiments, this description is not intended to be construed in a limiting sense. Various modifications and combinations of the illustrative embodiments, as well as other embodiments of this disclosure, are contemplated in reference to the description.

1. A method for producing a microstructured air-permeable environmental barrier membrane, the method comprising:
structuring a through hole into a substrate having two opposite surfaces, the through hole extending through the substrate between the two opposite surfaces; and
leaving the through hole uncovered, depositing one or more nanofibers onto at least one of the two opposite substrate surfaces by applying at least one of an electrospinning or blow-spinning fiber deposition process, such that the nanofibers combine into a nanofibrous membrane covering the previously uncovered through hole, the nanofibrous membrane being free-standing and mechanically compliant.

2. The method according to claim 1, further comprising:
microstructuring a carrier structure inside the through hole, the carrier structure being suspended by breakable beams, wherein depositing the nanofibers includes depositing the nanofibers onto the carrier structure; and
breaking the breakable beams and removing the carrier structure from the through hole for releasing the nanofibrous membrane.

3. The method according to claim 1, further comprising:
depositing an adhesion promotion layer onto at least one of the first surface or the second surface; and
wherein depositing the nanofibers includes depositing the nanofibers onto the adhesion promotion layer.

4. The method according to claim 1, further comprising:
performing the method of claim 1 on wafer-level, wherein the substrate is provided as a wafer comprising a plurality of the through holes; and
wherein depositing the nanofibers includes depositing the nanofibers onto at least one of the first surface or the second surface for covering the plurality of through holes in the wafer.

5. The method according claim 1, further comprising:
performing the method of claim 1 on chip-level, wherein the substrate is provided as a single chip having a single through hole; and
wherein depositing the nanofibers includes depositing the nanofibers onto at least one of the first surface or the second surface for covering the single through hole in the chip.

6. The method according claim 1, further comprising:
post-processing of the nanofibers by applying a solvent vaporization and/or a heat treatment for creating cross-linked nanofibers.

7. The method according claim 1, further comprising:
wherein depositing the nanofibers includes depositing nanofibers comprising different materials and/or different diameters among the nanofibers.

8. A method for producing a microstructured air-permeable environmental barrier membrane, the method comprising:
providing a substrate having a first surface and an second surface opposite the first surface,
depositing a sacrificial layer onto at least one of the first surface or the second surface,
structuring a through hole into the substrate, the through hole extending fully through the substrate between the first surface and the second surface, wherein the sacrificial layer covers the through hole;
depositing one or more nanofibers onto the sacrificial layer by applying at least one of an electrospinning or blow-spinning fiber deposition process, such that the nanofibers combine into a nanofibrous membrane; and
removing the sacrificial layer for releasing the nanofibrous membrane, wherein the nanofibrous membrane is released to be free-standing and mechanically compliant and covers the through hole.

9. The method according to claim 8, wherein depositing the sacrificial layer includes depositing a silicon oxide layer, and removing the sacrificial layer is performed by applying a chemical wet-etching process.

10. The method according to claim 9, wherein depositing the nanofibers includes depositing nanofibers comprising a material resistant against an etchant used in the chemical wet-etching process.

11. The method according to claim 8, wherein removing the sacrificial layer includes applying a high-temperature ashing process.

12. The method according to claim 11, wherein depositing the sacrificial layer includes depositing a sacrificial layer comprising a carbon-based material that is removable by the high-temperature ashing process.

13. The method according to claim 11, wherein depositing the nanofibers includes depositing nanofibers comprising at least one of a high-temperature stable polymer material, a ceramic-based material, or a metal oxide material that can withstand the high-temperature ashing process.

14. An environmental barrier chip with an air-permeable environmental barrier membrane, the environmental barrier chip comprising:
a substrate having a first surface and a second surface opposite the first surface, the substrate comprising a through hole extending through the first surface and the second surface; and
a nanofibrous membrane including a network of nanofibers and located on at least one of the first surface or the second surface, such that the nanofibrous membrane covers the through hole, the nanofibrous membrane being free-standing and mechanically compliant.

15. The environmental barrier chip according to claim 14, further comprising:
a carrier structure inside the through hole, the carrier structure being suspended by breakable beams.

16. The environmental barrier chip according to claim 14, further comprising:
an adhesion promotion layer covering at least one of the first surface or the second surface, wherein the nanofibrous membrane is located over the adhesion promotion layer.

17. The environmental barrier chip according to claim 14, wherein the nanofibrous membrane includes cross-linked nanofibers.

18. The environmental barrier chip according to claim 14, wherein the nanofibrous membrane includes nanofibers comprising different materials and/or different diameters among the nanofibers.

19. The environmental barrier chip according to claim 14, wherein the substrate is a wafer having a plurality of through holes, and wherein respective nanofibrous membranes respectively cover each of the through holes.

20. The environmental barrier chip according to claim 19, wherein each of the respective nanofibrous membranes are substantially identical.
